(19) United States
(12) Patent Application Publication
(10) Pub. No.: US 2026/0118621 A1
(43) Pub. Date: Apr. 30, 2026

(54) ILLUMINATION OPTICAL SYSTEM INCLUDING TEMPERATURE COMPENSATED APERTURE

(71) Applicant: SAMSUNG DISPLAY CO., LTD., YONGIN-SI (KR)

(72) Inventors: AKIFUMI SANGU, Yongin-si (KR); CHEOLHO PARK, Yongin-si (KR); YOUNGSU CHAE, Yongin-si (KR)

(21) Appl. No.: 19/009,090

(22) Filed: Jan. 3, 2025

(30) Foreign Application Priority Data
Mar. 19, 2024 (KR) 10-2024-0037786

(51) Int. Cl. G02B 7/00; G02B 5/00; G02B 17/08; G03F 7/00; G03F 7/20

(52) U.S. Cl. CPC G02B 7/008; G02B 5/006; G02B 17/0892; G03F 7/2002; G03F 7/70016; G03F 7/70075; G03F 7/701; G03F 7/7015; G03F 7/70891

(57) ABSTRACT

An illumination optical system includes: a mirror part that converges light; a light source part that is disposed at a first focus of the mirror part and emits the light; a first aperture that is disposed at a second focus different from the first focus of the mirror part, absorbs a portion of the light converged at a plane of the second focus, and transmits a first light; a lens part spaced apart from the mirror part with the first aperture interposed between the mirror part and the lens part; a second aperture that is disposed between the first aperture and the lens part, absorbs a portion of the first light, and transmits a second light; and a cooling member that compensates for a temperature of the second aperture.

### CROSS-REFERENCE TO RELATED APPLICATION

This application claims priority under 35 USC § 119 to Korean Patent Application No. 10-2024-0037786, filed on Mar. 19, 2024, in the Korean Intellectual Property Office, the content of which is herein incorporated by reference in its entirety.

### BACKGROUND

### 1. Technical Field

The present disclosure relates generally to an illumination optical system. More particularly, the present disclosure relates to an illumination optical system including a temperature compensated aperture.

### 2. Discussion of Related Art

An exposure apparatus may be an apparatus that transfers a pattern formed on a mask to a substrate or plate. The exposure apparatus may be an apparatus that illuminates the mask using an illumination optical system and transfers the pattern of the mask using a projection optical system. For example, the exposure apparatus may be utilized for manufacturing a flat panel display, a semiconductor device, or micro-electro mechanical systems (“MEMS”).

A light source of the exposure apparatus may be provided as a short arc-type discharge lamp. The short arc-type discharge lamp may be, for example an ultra-high pressure mercury lamp. The light emitted from the light source may illuminate the mask through a plurality of lenses (e.g., a condenser lens, a fly-eye lens, etc.).

### SUMMARY

Embodiments provide an illumination optical system with improved reliability of a lens part.

Embodiments provide an exposure apparatus including the illumination optical system.

An illumination optical system according to an embodiment of the present disclosure includes: a mirror part that converges light; a light source part that is disposed at a first focus of the mirror part and emits the light; a first aperture that is disposed at a second focus different from the first focus of the mirror part, absorbs a portion of the light converged at a plane of the second focus, and transmits a first light; a lens part spaced apart from the mirror part with the first aperture interposed between the mirror part and the lens part; a second aperture that is disposed between the first aperture and the lens part, absorbs a portion of the first light, and transmits a second light; and a cooling member that compensates for a temperature of the second aperture.

In an embodiment, the lens part may include a first lens that receives the second light and a support member supporting the first lens.

In an embodiment, the second aperture may absorb the portion of the first light traveling from the second focus toward the support member.

In an embodiment, the second light passing through the second aperture may not reach the lens part.

In an embodiment, the light source part may include a mercury lamp that emits ultraviolet light. A first diameter of the first aperture and a second diameter of the second aperture may satisfy an equation in which: following Equation 1.

$$0.83 d \frac{{f}_{2}}{{f}_{1}} \leq D 1 \leq D 2 \leq d \frac{{f}_{2}}{{f}_{1}} \leq D 3$$

wherein d is a distance (mm) between electrodes of the light source part, f₁ is a distance between the first focus and an intersection where an imaginary straight line connecting the first focus and the second focus and the mirror part meet, f₂ is a distance between the second focus and the intersection, and D1 is the first diameter (mm), D2 is the second diameter (mm), and D3 is a diameter (mm) of the first lens.

In an embodiment, the illumination optical system may further include a fly-eye lens part spaced apart from the second aperture with the first lens interposed between the fly-eye lens part and the second aperture.

In an embodiment, the mirror part defines an opening through which the light exits and has a shape of a portion of an ellipse, and the first aperture and the second aperture may be sequentially disposed along a direction parallel to an optical axis of the lens part.

In an embodiment, the cooling member may further compensate for a temperature of the first aperture.

An illumination optical system according to another embodiment of the present disclosure includes: a mirror part that converges light; a light source part that is disposed at a first focus of the mirror part and emits the light; a first aperture that is disposed at a second focus different from the first focus of the mirror part, reflects a portion of the light converged at a plane of the second focus, and transmits a first light; a lens part spaced apart from the mirror part with the first aperture interposed between the mirror part and the lens part; a second aperture that is disposed between the first aperture and the lens part, reflects a portion of the first light, and transmits a second light; and a cooling member that compensates for a temperature of the second aperture.

In an embodiment, the lens part may include a first lens that receives the second light and a support member supporting the first lens.

In an embodiment, the second aperture may reflect the portion of the first light traveling from the second focus toward the support member.

In an embodiment, the second light passing through the second aperture may not reach the lens part.

In an embodiment, the mirror part defines an opening through which the light exits and has a shape of a portion of an ellipse, and the first aperture and the second aperture may be sequentially disposed along a direction parallel to an optical axis of light traveling toward the lens part.

In an embodiment, the cooling member may further compensate for a temperature of the first aperture.

An exposure apparatus according to an embodiment of the present disclosure includes: an illumination optical system that illuminates a mask with light emitted from a light source part; and a projection optical system that projects an image of a pattern of the mask on a substrate. The illumination optical system includes: a mirror part that converges light, defines an opening through which the light exits, and has a shape of a portion of an ellipse; the light source part that is disposed at a first focus of the mirror part and emits the light; a first aperture that is disposed at a second focus different from the first focus of the mirror part, blocks a portion of the light converged at a plane of the second focus, and transmits a first light; a lens part spaced apart from the mirror part with the first aperture interposed between the mirror part and the lens part; a second aperture that is disposed between the first aperture and the lens part, blocks a portion of the first light, and transmits a second light; and a cooling member thermally connected to the second aperture.

In an embodiment, the lens part may include a first lens that receives the second light and a support member supporting the first lens.

In an embodiment, the second aperture may block the portion of the first light traveling from the second focus toward the support member among the first light.

In an embodiment, the first aperture and the second aperture may be sequentially disposed along a direction parallel to an optical axis of the lens part.

In an embodiment, the cooling member may be thermally connected to the first aperture, and the cooling member may further compensate for a temperature of the first aperture.

In an embodiment, the cooling member may further compensate for a temperature of the second aperture.

An illumination optical system according to an embodiment of the present disclosure may include a mirror part that converges light emitted from a light source part, a first aperture that blocks a portion of the light converged by the mirror and transmits a first light, a second aperture that blocks a portion of the first light and transmits a second light, a lens part spaced apart from the mirror part with the first aperture and the second aperture interposed therebetween, and a cooling member that compensates for a temperature of the second aperture. The lens part may include a first lens and a support member supporting the first lens.

The second aperture may absorb light traveling toward the support member among the first light. Accordingly, the second light may be incident on the first lens and may be blocked from reaching the support member. Accordingly, a temperature rise of the support member as the second light is incident on the support member may be reduced.

The cooling member may suppress a temperature rise of the second aperture. That is, heat transferred to the second aperture by the light may be transferred to the cooling member. Accordingly, the temperature of the second aperture may be compensated, and the temperature rise of the support member adjacent to the second aperture may be reduced. By compensating for a temperature rise of the second aperture, a problem of misalignment of the first lens or a problem of decreased transmittance of the first lens may be suppressed. In other words, the reliability of the lens part may be improved.

### BRIEF DESCRIPTION OF THE DRAWINGS

Illustrative, non-limiting embodiments will be more clearly understood from the following detailed description in conjunction with the accompanying drawings.

FIG. 1 is a side view illustrating an exposure apparatus according to an embodiment of the present disclosure.

FIG. 2 is a view illustrating an embodiment of the illumination optical system of FIG. 1.

FIG. 3 is a view illustrating a path of light in an illumination optical system according to a comparative example.

FIG. 4 is an enlarged view of the area A of FIG. 2.

FIG. 5 is a view illustrating another embodiment of the illumination optical system of FIG. 1.

FIG. 6 is an enlarged view of the area B of FIG. 5.

### DETAILED DESCRIPTION

Hereinafter, embodiments of the present disclosure will be described in detail with reference to the accompanying drawings. Inventive concepts may be implemented in various modifications and have various forms. It is to be understood, however, that the inventive concepts are not intended to be limited to the particular forms disclosed, but on the contrary, is intended to cover all modifications, equivalents, and alternatives falling within the spirit and scope of the inventive concepts. The same reference numerals are used for the same components in the drawings, and redundant descriptions of the same components may be omitted.

In the drawings, the thicknesses, the ratios, and the dimensions of the elements may be exaggerated for effective description of the technical contents.

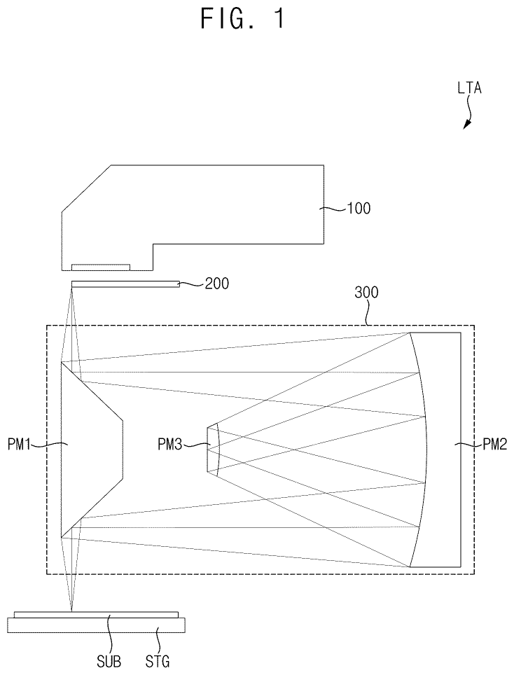

FIG. 1 is a side view illustrating an exposure apparatus according to an embodiment of the present disclosure.

Referring to FIG. 1, an exposure apparatus LTA according to an embodiment of the present disclosure may include an illumination optical system 100, a projection optical system 300, and a stage STG. The exposure apparatus LTA may be a lithography apparatus that uses light including a plurality of wavelength ranges to illuminate a mask 200 and transfers a pattern of the mask 200 onto a substrate SUB. For example, the exposure apparatus LTA may be utilized to manufacture a flat panel display, a semiconductor device, or micro-electro mechanical systems (“MEMS”).

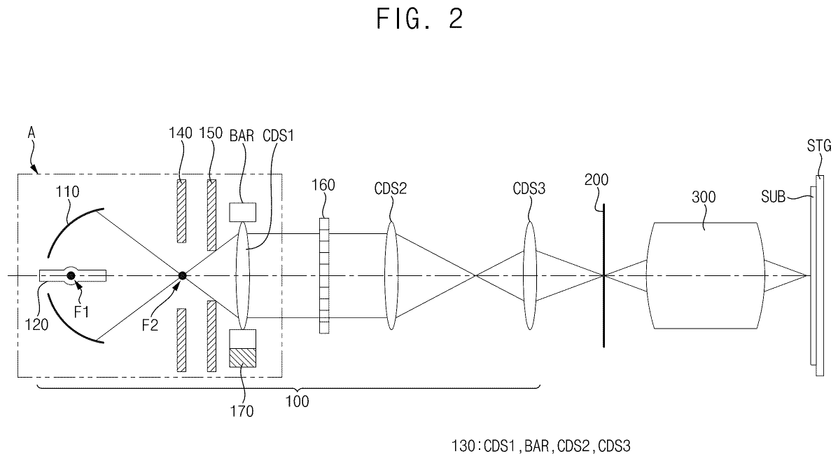

The illumination optical system 100 may include a light source part 120 (see FIG. 2) that may emit light. The light may have a plurality of wavelength ranges. The illumination optical system 100 may use the light to illuminate the mask 200.

The projection optical system 300 may project the light onto the substrate SUB. The projection optical system 300 may project an image of a pattern, which is formed on the mask 200, onto the substrate SUB. The mask 200 may be disposed on an object plane of the projection optical system 300. The substrate SUB may be disposed on an image plane of the projection optical system 300. For example, the projection optical system 300 may include a plurality of projection mirrors that may reflect light. The projection mirrors may include a first projection mirror PM1, a second projection mirror PM2, and a third projection mirror PM3. The third projection mirror PM3 may be disposed between the first projection mirror PM1 and the second projection mirror PM2.

Light passing through the mask 200 may be reflected from the projection mirrors. The light from the mask 200 may be reflected by the first projection mirror PM1, the second projection mirror PM2, and the third projection mirror PM3. For example, the light from the mask 200 may be reflected in, in order by the first projection mirror PM1, the second projection mirror PM2, the third projection mirror PM3, the second projection mirror PM2, and the first projection mirror PM1. Accordingly, the projection optical system 300 may form a projected image of the mask 200 on the substrate SUB. When the projection optical system 300 is configured as a reflective optical system, a chromatic aberration of light from the light source part may be relatively small compared to when the projection optical system 300 is configured as a refractive optical system.

The substrate SUB may be disposed on the stage STG. Specifically, the substrate SUB may be loaded on the stage STG. A pattern of the mask 200 may transferred to the substrate SUB may be loaded on the stage STG. The stage STG may include an upper surface for receiving the stage STG. The stage STG may include a flat upper surface. For example, the stage STG may include an electrostatic chuck that stationarily secures the substrate SUB by electrostatic force.

FIG. 2 is a view illustrating an embodiment of the illumination optical system 100 of FIG. 1.

Referring to FIG. 2, the illumination optical system 100 according to an embodiment of the present disclosure may include a mirror part 110, a light source part 120, a lens part 130, a first aperture 140, a second aperture 150, and a fly-eye lens part 160. The lens part 130 may include a first lens CDS1, a support member BAR, a second lens CDS2, and a third lens CDS3.

The light source part 120 may emit light. The mirror part 110 may focus the light emitted from the light source part 120. The mirror part 110 may define an opening through which the light emitted from the light source part 120 may exit. The mirror part 110 may have a shape to focus the light. In an embodiment, the mirror part 110 may have a shape of a portion of an ellipse. The light source part 120 may be disposed at a first focus F1. When the light source part 120 is disposed at the first focus F1, the mirror part 110 may converge the light emitted from the light source part 120 to a second focus F2.

The light source part 120 may be disposed at the first focus F1 of the mirror part 110. The light source part 120 may emit light including a plurality of wavelength ranges. For example, the light source part 120 may emit broadband light. In an embodiment, the light source part 120 may include a mercury lamp that may emit ultraviolet light. In this case, the light source part 120 may emit light having a plurality of peak wavelengths (e.g., an i-line at about 365 nanometers, an h-line at about 405 nanometers, and a g-line at about 436 nanometers). This peak wavelengths may be visualized as spectral lines.

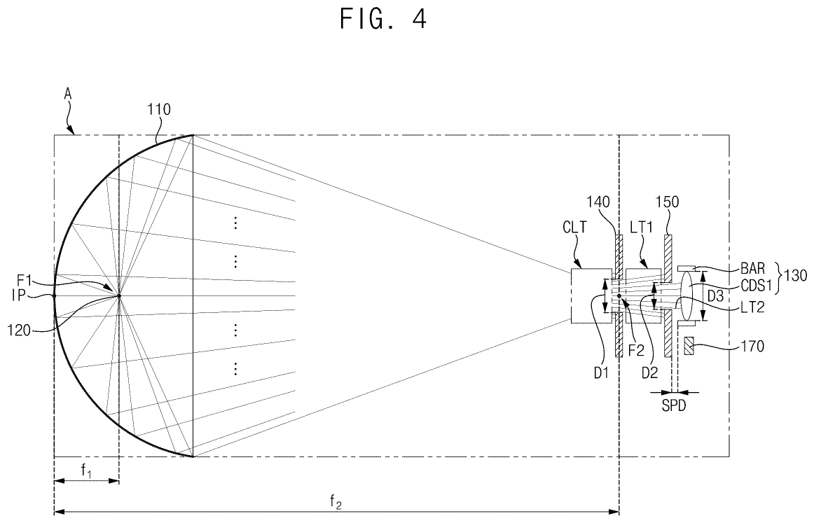

The first aperture 140 may be disposed at the second focus F2 of the mirror part 110. The first aperture 140 may adjust the amount of light transmitted. Specifically, the first aperture 140 may block a portion of the light converged (e.g., a converged light CLT of FIG. 4) to a plane of the second focus F2. In an embodiment, the first aperture 140 may absorb a portion of the converged light. For example, the first aperture 140 may block a portion of the converged light that is traveling toward the second aperture 150. In addition, the first aperture 140 may transmit a first light (LT1, see FIG. 4) among the converged light. In this case, the first light may be defined as light that is not absorbed by the first aperture 140 among the converged light.

The second aperture 150 may be disposed between the first aperture 140 and the lens part 130. The second aperture 150 may adjust the amount of light transmitted. Specifically, the second aperture 150 may block a portion of the first light that passes through the first aperture 140. In an embodiment, the second aperture 150 may absorb a portion of the first light. In addition, the second aperture 150 may transmit a second light (LT2, see FIG. 4) among the first light. In this case, the second light may be defined as light that is not absorbed by the second aperture 150 among the first light.

In an embodiment, the first aperture 140 and the second aperture 150 may be sequentially disposed along a direction parallel to an optical axis of the lens part 130. In some embodiments, the optical axis of the lens part 130 may be the same as an optical axis of the illumination optical system 100. In other words, the first aperture 140 and the second aperture 150 may be disposed on the same optical path of light traveling toward the lens part 130. The light converged by the mirror part 110 may be incident on the first aperture 140, and the first light passing through the first aperture 140 may be incident on the second aperture 150.

The illumination optical system 100 according to an embodiment of the present disclosure may further include a cooling member 170 to compensate for a temperature of the second aperture 150. A detailed description thereof is described herein with reference to FIG. 4.

In an embodiment, the illumination optical system 100 may include the first aperture 140 and the second aperture 150 disposed between the mirror part 110 and the lens part 130. However, the number of apertures included the illumination optical system 100 is not limited thereto. For example, the illumination optical system 100 may further include a third aperture disposed between the first aperture 140 and the second aperture 150.

The lens part 130 may be spaced apart from the mirror part 110 with the first aperture 140 and the second aperture 150 interposed therebetween. The lens part 130 may include the first lens CDS1 and the support member BAR. The support member BAR may support the first lens CDS1.

The support member BAR may receive the first lens CDS1. For example, the support member BAR may be a bar type holder, a ring mount, a jaw mount, or a component mount. Embodiments are not limited to the examples described herein, and the support member BAR may be variously configured.

The first lens CDS1 may receive the second light that passes through the second aperture 150. The first lens CDS1 may shape the second light into parallel light. The light shaped as parallel light by the first lens CDS1 may be incident on the fly-eye lens part 160.

The fly-eye lens part 160 may be spaced apart from the second aperture 150 with the first lens CDS1 interposed therebetween. The fly-eye lens part 160 may include a plurality of microlenses. The fly-eye lens part 160 may form a secondary light source on an exit surface of the fly-eye lens part 160 from light incident on an incident surface of the fly-eye lens part 160.

Light exited from the fly-eye lens part 160 may pass through the second lens CDS2 and the third lens CDS3, and may illuminate the mask 200. For example, the fly-eye lens part 160 may be referred to as an optical integrator.

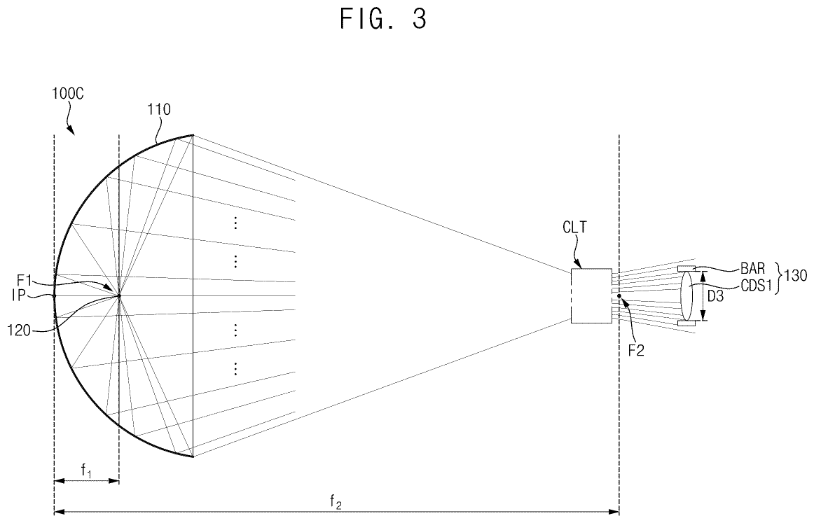

FIG. 3 is a view illustrating a path of light in an illumination optical system according to a comparative example. FIG. 4 is an enlarged view of the area A of FIG. 2. For example, FIG. 4 is a view illustrating a path of light in the illumination optical system 100 according to an embodiment of the present disclosure.

Referring to FIG. 3, an illumination optical system 100C according to a comparative example may include a mirror part 110, a light source part 120, and a lens part 130. The lens part 130 may include a first lens CDS1 and a support member BAR supporting the first lens CDS1.

The illumination optical system 100C according to the comparative example may be substantially the same as the illumination optical system 100 described with reference to FIG. 2, except that the illumination optical system 100C does not include the first aperture and the second aperture which may be disposed between the mirror part 110 and the lens part 130.

The light source part 120 disposed at a first focus F1 of the mirror part 110 may emit light. The mirror part 110 may converge the light emitted from the light source part 120 to a second focus F2. In an embodiment, the light source part 120 may include a mercury lamp that emits ultraviolet light. For example, a distance between electrodes (or, an arc length) of the light source part 120 may be about 10 millimeters, but the present disclosure is not limited thereto. In this case, the converged light CLT, converged by the mirror part 110 may not converge to a single point. In other words, the converged light CLT may form a converged plane at a distance at or about the second focus F2. The converged plane may extend substantially perpendicular to the optical axis of the illumination optical system 100.

The converged light CLT may pass through the second focus F2 and may proceed toward the lens part 130. In this case, the converged light CLT may reach the first lens CDS1 and the support member BAR. When the converged light CLT is incident on the support member BAR, a temperature of the support member BAR may increase. When the temperature of the support member BAR increases, a misalignment of the first lens CDS1 may occur. For example, the misalignment of the first lens CDS1 may occur due to a difference in thermal expansion between the support member BAR and the first lens CDS1. In addition, when the temperature of the support member BAR increases, more foreign material may be absorbed into the lens part 130, and a transmittance of the first lens CDS1 may decrease.

Referring to FIG. 4, the illumination optical system 100 according to an embodiment of the present disclosure may include the mirror part 110, the light source part 120, the lens part 130, the first aperture 140, the second aperture 150, and a cooling member 170. The lens part 130 may include the first lens CDS1 and the support member BAR supporting the first lens CDS1.

The light source part 120 may be configured to emit light. The light source part 120 may be disposed at the first focus F1 of the mirror part 110. The light source part 120 disposed at the first focus F1 of the mirror part 110 may emit light. The mirror part 110 may converge the light emitted from the light source part 120 to the second focus F2. A distance between electrodes (or, an arc length) of the light source part 120 may be about 10 millimeters, but the present disclosure is not limited thereto. The converged light CLT converged by the mirror part 110 may not converge to a single point. In other words, the converged light CLT may form a converged plane at a distance at or about the second focus F2. The converged plane may extend substantially perpendicular to the optical axis of the illumination optical system 100.

A portion of the converged light CLT may be incident from the second focus F2 on the first aperture 140. The first aperture 140 may absorb a portion of the converged light CLT. The portion of the converged light CLT absorbed by the first aperture 140 may be light that is not used to illuminate the mask 200 (see FIG. 2). In other words, the portion of the converged light CLT absorbed by the first aperture 140 may not contribute to the illuminance of the light that illuminates the mask. Accordingly, even though the portion of the converged light CLT is absorbed by the first aperture 140, the illuminance of the light that illuminates the mask may be substantially ensured. For example, a first diameter D1 of the first aperture 140 may be about 50 millimeters to about 60 millimeters. However, the first diameter D1 of the first aperture 140 is not limited thereto.

The first aperture 140 may transmit a first light LT1 portion of the converged light CLT. In this case, the first light LT1 may be defined as the light that is not absorbed by the first aperture 140 among the converged light CLT.

The first light LT1 that passes through the first aperture 140 may be incident on the second aperture 150. The second aperture 150 may absorb a portion of the first light LT1. The portion of the first light LT1 absorbed by the second aperture 150 may hardly contribute to the illuminance of the light that illuminates the mask. Accordingly, even though the portion of the first light LT1 is absorbed by the second aperture 150, the illuminance of the light that illuminates the mask may be substantially ensured. For example, a second diameter D2 of the second aperture 150 may be about 60 millimeters. However, the second diameter D2 of the second aperture 150 is not limited thereto.

In an embodiment, the second aperture 150 may absorb a portion of the light traveling toward the support member BAR among the first light LT1. In other words, the second aperture 150 may absorb a first portion of light among the first light LT1 that would be incident on the support member BAR if not absorbed. The second aperture 150 may transmit a second portion of light traveling toward the first lens CDS1 among the first light LT1.

The second aperture 150 may transmit a second light LT2 portion of the first light LT1. In this case, the second light LT2 may be defined as light that is not absorbed by the second aperture 150 among the first light LT1. In addition, the second light LT2 may refer to light traveling toward the first lens CDS1.

The second light LT2 that passes through the second aperture 150 may proceed toward the lens part 130. In this case, the second light LT2 may be incident on the first lens CDS1. That is, the second light LT2 may be substantially blocked from reaching the support member BAR. In other words, as the second aperture 150 may absorb the light traveling toward the support member BAR among the first light LT1, the amount of light incident on the support member BAR may be reduced. For example, less than about 10 percent of the second light LT2 may be incident on the support member BAR. In an other example, less than about 5 percent of the second light LT2 may be incident on the support member BAR. In yet another example, less than about 1 percent of the second light LT2 may be incident on the support member BAR. Accordingly, a temperature rise of the support member BAR as the second light LT2 is incident on the support member BAR may be reduced. As a result, a problem of misalignment of the first lens CDS1 or a problem of decreased transmittance of the first lens CDS1 may be suppressed or prevented. In other words, the reliability of the lens part 130 may be improved.

In an embodiment, the first diameter D1 of the first aperture 140 and the second diameter D2 of the second aperture 150 may satisfy Equation 1 below.

$$0. 83 d \frac{{f}_{2}}{{f}_{1}} \leq D 1 \leq D 2 \leq d \frac{{f}_{2}}{{f}_{1}} \leq D 3 \qquad [ Equation 1 ]$$

In Equation 1, d is a distance between electrodes of the light source part, and the unit is millimeter (mm). f₁ is a distance between the first focus F1 and an intersection IP where an imaginary straight line connecting the first focus F1 and the second focus F2 and the mirror part 110 meet. f₂ is a distance between the second focus F2 and the intersection IP. D1 is the first diameter D1 of the first aperture 140, and the unit is millimeter (mm). D2 is the second diameter D2 of the second aperture 150, and the unit is millimeter (mm). D3 is a diameter of the first lens CDS1, and the unit is millimeter (mm).

For example, when d is about 10 millimeters, f₁ is about 150 millimeters, and f₂ is about 900 millimeters, the first diameter D1 of the first aperture 140 and the second diameter D2 of the second aperture 150 may satisfy Equation 2 below.

$$49.8 \leq D 1 \leq D 2 \leq 60 \qquad [ Equation 2 ]$$

In this case, the first diameter D1 of the first aperture 140 may be about 50 millimeters and the second diameter D2 of the second aperture 150 may be about 60 millimeters, but the present disclosure is not limited thereto.

The second aperture 150 may be disposed adjacent to the lens part 130. For example, a separation distance SPD between the second aperture 150 and the support member BAR may be about 30 millimeters. As the second aperture 150 and the lens part 130 are adjacent to each other, the temperature rise of the second aperture 150 may affect the lens part 130. Specifically, as the second aperture 150 may absorb light traveling toward the support member BAR from the first light LT1, the temperature of the second aperture 150 may increase, and the temperature rise of the second aperture 150 may affect the lens part 130.

To suppress or prevent a rise in the temperature of the second aperture 150, the illumination optical system 100 according to an embodiment of the present disclosure may include a cooling member 170. The cooling member 170 may compensate for the temperature of the second aperture 150. For example, the cooling member 170 may be thermally connected to the second aperture 150, and may transfer heat away from the second aperture 150. Heat transferred to the second aperture 150 by the light may be transferred to the cooling member 170 having a relatively lower temperature than the second aperture 150. Accordingly, the temperature of the second aperture 150 may be compensated, and the temperature rise of the support member BAR adjacent to the second aperture 150 may be further reduced. For example, the cooling member 170 may include a Peltier element. In the case of a Peltier element, the cooling member 170 may by mounted on the second aperture 150. For example, the cooling member 170 may include a cooling water supply pipe through which cooling water flows. The cooling water supply pipe may be disposed on a portion of the second aperture 150 and may provide a thermal connection for transferring heat away from the second aperture 150. However, the present disclosure is not limited thereto, and the cooling member 170 may include various cooling means known in the art. In an embodiment, the cooling member 170 may compensate for the temperature of the second aperture 150 and for a temperature of the lens part 130.

In an embodiment, the cooling member 170 may compensate for a temperature of the first aperture 140 and the temperature of the second aperture 150. For example, the cooling member 170 may be thermally connected to the first aperture 140 and the second aperture 150, and may transfer heat away from the first aperture 140 and the second aperture 150. As the first aperture 140 absorbs a portion of the converged light CLT, the temperature of the first aperture 140 may be increased by the portion of the converged light CLT that is absorbed. Heat transferred to the first aperture 140 may be transferred to the cooling member 170 having a relatively lower temperature than the first aperture 140. Accordingly, the temperature of the first aperture 140 may be compensated, and the temperature rise of the second aperture 150 adjacent to the first aperture 140 may be reduced.

Hereinafter, example effects of the present disclosure will be described below with reference to Table 1, FIG. 3, and FIG. 4.

A first light quantity, a second light quantity, and a third light quantity are given as measurements of illumination optical systems satisfying Comparative Example, Example 1, Example 2, Example 3, Example 4, Example 5, and Example 6. The first light quantity is defined as the amount of light absorbed by the second aperture 150. The second light quantity is defined as the amount of light incident on the support member BAR. The third light quantity is defined as the amount of light illuminating the mask (200, see FIG. 2). A distance between the electrodes of the light source part 120 (or, an arc length) is about 10 millimeters. A distance f₁ between the first focus F1 and the intersection IP where an imaginary straight line connecting the first focus F1 and the second focus F2 and the mirror part 110 meet is about 150 millimeters. A distance f₂ between the second focus F2 and the intersection IP is about 900 millimeters. A diameter D3 of the first lens CDS1 is about 80 millimeters.

The illumination optical systems (e.g., the illumination optical system 100 of FIG. 4) satisfying the Example 1, the Example 2, and the Example 3 include the first aperture 140 and the second aperture 150 disposed between the mirror part 110 and the lens part 130. The first aperture 140 and the second aperture 150 absorb respective portions of light. The first diameter D1 of the first aperture 140 is about 50 millimeters. The second diameter D2 of the second aperture 150 is about 60 millimeters. In the illumination optical system satisfying the Example 1, the separation distance SPD between the second aperture 150 and the support member BAR is about 30 millimeters. In the illumination optical system satisfying the Example 2, the separation distance SPD between the second aperture 150 and the support member BAR is about 40 millimeters. In the illumination optical system satisfying the Example 3, the separation distance SPD between the second aperture 150 and the support member BAR is about 50 millimeters.

The illumination optical systems (e.g., the illumination optical system 100 of FIG. 4) satisfying the Example 4, the Example 5, and the Example 6 include the first aperture 140 and the second aperture 150 disposed between the mirror part 110 and the lens part 130. The first aperture 140 and the second aperture 150 absorb a portion of light. The first diameter D1 of the first aperture 140 is about 60 millimeters. The second diameter D2 of the second aperture 150 is about 60 millimeters. In the illumination optical system satisfying the Example 4, the separation distance SPD between the second aperture 150 and the support member BAR is about 30 millimeters. In the illumination optical system satisfying the Example 5, the separation distance SPD between the second aperture 150 and the support member BAR is about 40 millimeters. In the illumination optical system satisfying the Example 6, the separation distance SPD between the second aperture 150 and the support member BAR is about 50 millimeters.

The illumination optical system (e.g., the illumination optical system 100C of FIG. 3) satisfying the Comparative Example does not include the first aperture 140 and the second aperture 150 that may be disposed between the mirror part 110 and the lens part 130.

As a result, referring to Table 1 below, when compared to the illumination optical system satisfying the Comparative Example, the amount of light incident on the support member BAR may be relatively reduced in the illumination optical systems satisfying the Example 1, the Example 2, the Example 3, the Example 4, the Example 5, and the Example 6.

In addition, when compared to the illumination optical system satisfying the Comparative Example, the amount of light illuminating the mask may be substantially ensured in the illumination optical systems satisfying the Example 1, the Example 2, the Example 3, the Example 4, the Example 5, and the Example 6.

TABLE 1

| | Amount of light | Amount of light | Amount of light |
|---|---|---|---|
| | absorbed by the | incident on the | illuminating the |
| | second aperture | support member | mask |
| | (relative value) | (relative value) | (relative value) |
| Comparative | — | 332 | 272 |
| Example | | | |
| Example 1 | 214 | 0 | 257 |
| Example 2 | 166 | 11 | 264 |
| Example 3 | 113 | 49 | 268 |
| Example 4 | 287 | 0 | 258 |
| Example 5 | 238 | 11 | 265 |
| Example 6 | 184 | 49 | 269 |

From these results, it can be seen that by absorbing a portion of light by the first aperture 140 and the second aperture 150 disposed between the mirror part 110 and the lens part 130, the illumination optical system 100 may reduce the temperature rise of the support member BAR without substantially reducing the illuminance of light that illuminates the mask.

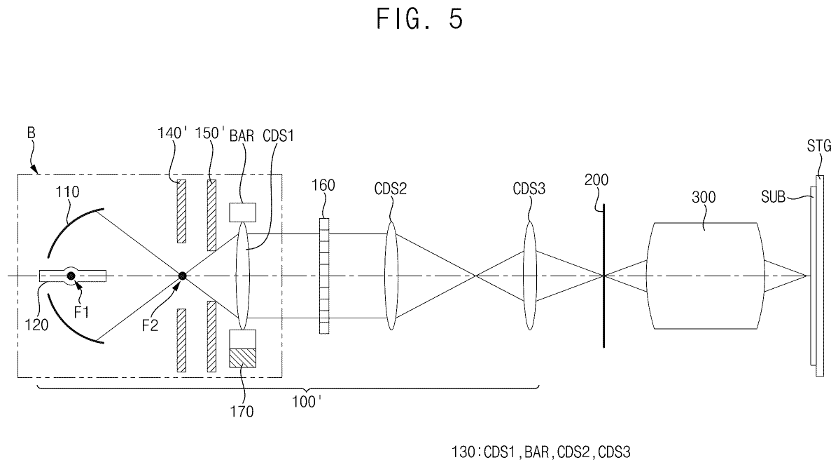

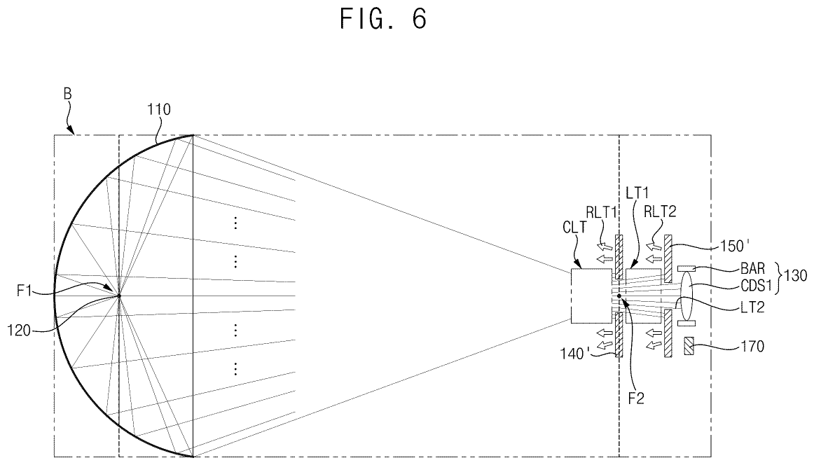

FIG. 5 is a view illustrating another embodiment of the illumination optical system of FIG. 1. FIG. 6 is an enlarged view of the area B of FIG. 5. For example, FIG. 6 is a view illustrating a path of light in the illumination optical system 100′ according to another embodiment of the present disclosure.

Referring to FIG. 5 and FIG. 6, a illumination optical system 100′ according to another embodiment of the present disclosure may include the mirror part 110, the light source part 120, the lens part 130, a first aperture 140′, a second aperture 150′, and the fly-eye lens part 160. The lens part 130 may include the first lens CDS1, the support member BAR, the second lens CDS2, and the third lens CDS3.

The illumination optical system 100′ may be substantially the same as the illumination optical system 100 described above with reference to FIG. 2 and FIG. 3. In the illumination optical system 100′, the first aperture 140′ and the second aperture 150′ reflect a portion of the light. Hereinafter, redundant descriptions of the illumination optical system 100 as described with reference to FIG. 2 and FIG. 3 may be omitted or summarized.

The light source part 120 disposed at the first focus F1 of the mirror part 110 may emit light. The mirror part 110 may converge the light emitted from the light source part 120 to the second focus F2. The converged light CLT, converged by the mirror part 110 may not converge to a single point. In other words, the converged light CLT may form a converged plane at a distance at or about the second focus F2. The converged plane may extend substantially perpendicular to the optical axis of the illumination optical system 100′.

The first aperture 140′ may be disposed at the second focus F2 of the mirror part 110. The converged light CLT may be incident from the second focus F2 on the first aperture 140′. The first aperture 140′ may adjust the amount of light transmitted there-through. Specifically, the first aperture 140′ may block a portion of light converged at the second focus F2. In an embodiment, the first aperture 140′ may reflect a portion of the converged light CLT. The portion of the converged light CLT reflected by the first aperture 140′ may be light that is not used to illuminate the mask 200. In other words, the portion of the converged light CLT reflected by the first aperture 140′ may not contribute to the illuminance of the light that illuminates the mask 200. Accordingly, even though the portion of the converged light CLT is absorbed by the first aperture 140′, the illuminance of the light that illuminates the mask 200 may be substantially ensured. A first reflected light RLT1 of FIG. 6 may be defined as light reflected from the first aperture 140′ among the converged light CLT.

In addition, the first aperture 140′ may transmit a first light LT1 portion of the converged light CLT. In this case, the first light LT1 may be defined as light that is not absorbed by the first aperture 140′ among the converged light CLT.

The first light LT1 that passes through the first aperture 140′ may be incident on the second aperture 150′. The second aperture 150′ may be disposed between the first aperture 140′ and the lens part 130. The second aperture 150′ may adjust the amount of light transmitted. Specifically, the second aperture 150′ may block a portion of the first light LT1 that passes through the first aperture 140′. In an embodiment, the second aperture 150′ may reflect the portion of the first light LT1. The portion of the first light LT1 reflected by the second aperture 150′ may not substantially contribute to the illuminance of the light that illuminates the mask 200. Accordingly, even though the portion of the first light LT1 is reflected by the second aperture 150′, the illuminance of the light that illuminates the mask 200 may be substantially ensured. A second reflected light RLT2 of FIG. 6 may be defined as light reflected from the second aperture 150′ among the first light LT1.

In an embodiment, the second aperture 150′ may reflect light traveling toward the support member BAR among the first light LT1. In other words, the second aperture 150′ may reflect light traveling toward the support member BAR and may transmit light traveling toward the first lens CDS1 among the first light LT1.

The second aperture 150′ may transmit a second light LT2 among the first light LT1. In this case, the second light LT2 may be defined as light that is not reflected by the second aperture 150′ among the first light LT1. In addition, the second light LT2 may refer to light traveling toward the first lens CDS1.

The second light LT2 that passes through the second aperture 150 may proceed toward the lens part 130. In this case, the second light LT2 may be incident on the first lens CDS1. That is, a small portion of the second light LT2 may reach the support member BAR. In other words, as the second aperture 150′ may reflect the light traveling toward the support member BAR among the first light LT1, the amount of light incident on the support member BAR may be reduced. Accordingly, a temperature rise of the support member BAR as the second light LT2 is incident on the support member BAR may be reduced. As a result, a problem of misalignment of the first lens CDS1 or a problem of decreased transmittance of the first lens CDS1 may be suppressed or prevented. In other words, the reliability of the lens part 130 may be improved.

The second aperture 150′ may be disposed adjacent to the lens part 130. For example, a separation distance between the second aperture 150′ and the support member BAR may be about 30 millimeters. As the second aperture 150′ and the lens part 130 are adjacent to each other, the temperature rise of the second aperture 150′ may affect the lens part 130.

In the illumination optical system 100′ according to another embodiment of the present disclosure, the first aperture 140′ and the second aperture 150′ may reflect light. As the second aperture 150′ reflects light traveling toward the support member BAR, the temperature rise of the second aperture 150′ may be relatively small since the second aperture 150′ may not absorb the light. As the temperature of the second aperture 150′ increases may be small, the effect on the lens part 130 adjacent to the second aperture 150′ may be small.

In addition, the illumination optical system 100′ according to another embodiment of the present disclosure may include a cooling member 170 that compensates for the temperature of the second aperture 150′ and a temperature rise of the second aperture 150′ may be suppressed. Heat transferred to the second aperture 150′ may be transferred to the cooling member 170, which may have a relatively lower temperature than the second aperture 150′. Accordingly, the temperature of the second aperture 150′ may be compensated, and the temperature rise of the support member BAR adjacent to the second aperture 150′ may be reduced. In an embodiment, the cooling member 170 may compensate for the temperature of the second aperture 150′ and for a temperature of the lens part 130.

In an embodiment, the cooling member 170 may compensate for a temperature of the first aperture 140′ and the temperature of the second aperture 150′.

Aspects of the present disclosure may be applied to an exposure apparatus for manufacturing display devices or semiconductor devices. For example, the present disclosure is applicable to various display devices such as display devices for vehicles, ships and aircraft, portable communication devices, display devices for exhibition or information transmission, or medical display devices.

The foregoing is illustrative of embodiments of the present disclosure, and is not to be construed as limiting thereof. Although embodiments have been described with reference to the figures, those skilled in the art will readily appreciate that many variations and modifications may be made therein without departing from the spirit and scope of the present disclosure as defined in the appended claims.

What is claimed is:

1. An illumination optical system comprising:
a mirror part that converges light;
a light source part that is disposed at a first focus of the mirror part and emits the light;
a first aperture that is disposed at a second focus different from the first focus of the mirror part, absorbs a portion of the light converged at a plane of the second focus, and transmits a first light;
a lens part spaced apart from the mirror part with the first aperture interposed between the mirror part and the lens part;
a second aperture that is disposed between the first aperture and the lens part, absorbs a portion of the first light, and transmits a second light; and
a cooling member that compensates for a temperature of the second aperture.

2. The illumination optical system of claim 1, wherein the lens part includes:
a first lens that receives the second light; and
a support member supporting the first lens.

3. The illumination optical system of claim 2, wherein the second aperture absorbs the portion of the first light traveling from the second focus toward the support member.

4. The illumination optical system of claim 2, wherein the second light passing through the second aperture does not reach the lens part.

5. The illumination optical system of claim 2,
wherein the light source part includes a mercury lamp that emits ultraviolet light, and
wherein a first diameter of the first aperture and a second diameter of the second aperture satisfy an equation in which:
$$0. 83 d \frac{{f}_{2}}{{f}_{1}} \leq D 1 \leq D 2 \leq d \frac{{f}_{2}}{{f}_{1}} \leq D 3$$
wherein d is a distance (mm) between electrodes of the light source part,
f₁ is a distance between the first focus and an intersection where an imaginary straight line connecting the first focus and the second focus and the mirror part meet,
f₂ is a distance between the second focus and the intersection, and
D1 is the first diameter (mm), D2 is the second diameter (mm), and D3 is a diameter (mm) of the first lens.

6. The illumination optical system of claim 2, further comprising:
a fly-eye lens part spaced apart from the second aperture with the first lens interposed between the fly-eye lens part and the second aperture.

7. The illumination optical system of claim 1, wherein the mirror part defines an opening through which the light exits and has a shape of a portion of an ellipse, and
the first aperture and the second aperture are sequentially disposed along a direction parallel to an optical axis of the lens part.

8. The illumination optical system of claim 1, wherein the cooling member further compensates for a temperature of the first aperture.

9. An illumination optical system comprising:
a mirror part that converges light;
a light source part that is disposed at a first focus of the mirror part and emits the light;
a first aperture that is disposed at a second focus different from the first focus of the mirror part, reflects a portion of the light converged at a plane of the second focus, and transmits a first light;
a lens part spaced apart from the mirror part with the first aperture interposed between the mirror part and the lens part;
a second aperture that is disposed between the first aperture and the lens part, reflects a portion of the first light, and transmits a second light; and
a cooling member that compensates for a temperature of the second aperture.

10. The illumination optical system of claim 9, wherein the lens part includes:
a first lens that receives the second light; and
a support member supporting the first lens.

11. The illumination optical system of claim 10, wherein the second aperture reflects the portion of the first light traveling from the second focus toward the support member.

12. The illumination optical system of claim 10, wherein the second light passing through the second aperture does not reach the lens part.

13. The illumination optical system of claim 9, wherein the mirror part defines an opening through which the light exits and has a shape of a portion of an ellipse, and
the first aperture and the second aperture are sequentially disposed along a direction parallel to an optical axis of the lens part.

14. The illumination optical system of claim 9, wherein the cooling member further compensates for a temperature of the first aperture.

15. An exposure apparatus comprising:
an illumination optical system that illuminates a mask with light emitted from a light source part; and
a projection optical system that projects an image of a pattern of the mask onto a substrate,
wherein the illumination optical system comprises:
a mirror part that converges light, defines an opening through which the light exits, and has a shape of a portion of an ellipse;
the light source part that is disposed at a first focus of the mirror part and emits the light;
a first aperture that is disposed at a second focus different from the first focus of the mirror part, blocks a portion of the light converged at a plane of the second focus, and transmits a first light;
a lens part spaced apart from the mirror part with the first aperture interposed between the mirror part and the lens part;
a second aperture that is disposed between the first aperture and the lens part, blocks a portion of the first light, and transmits a second light; and
a cooling member thermally connected to the second aperture.

16. The exposure apparatus of claim 15, wherein the lens part includes:
a first lens that receives the second light; and
a support member supporting the first lens.

17. The exposure apparatus of claim 16, wherein the second aperture blocks the portion of the first light traveling from the second focus toward the support member.

18. The exposure apparatus of claim 15, wherein the first aperture and the second aperture are sequentially disposed along a direction parallel to an optical axis of the lens part.

19. The exposure apparatus of claim 15, wherein the cooling member is thermally connected to the first aperture, and the cooling member further compensates for a temperature of the first aperture.

20. The exposure apparatus of claim 15, wherein the cooling member compensates for a temperature of the second aperture.
